(19) United States
(12) Patent Application Publication
(10) Pub. No.: US 2008/0220256 A1
(43) Pub. Date: Sep. 11, 2008

(54) METHODS OF COATING CARBON/CARBON COMPOSITE STRUCTURES

(75) Inventors: Rabi S. Bhattacharya, Beavercreek, OH (US); Peng He, Dayton, OH (US); Yongli Xu, Centerville, OH (US)

Correspondence Address: DINSMORE & SHOHL LLP, ONE DAYTON CENTRE, ONE SOUTH MAIN STREET, SUITE 1300, DAYTON, OH, 45402-2023, US

(73) Assignee: UES, INC., Dayton, OH (US)

(21) Appl. No.: 11/684,362

(22) Filed: Mar. 9, 2007

(51) Int. Cl. B32B 9/04; C23C 16/00; C23C 16/24; H05H 1/48

(52) U.S. Cl. 428/408; 427/249.16; 427/580; 427/589

(57) ABSTRACT

Embodiments of a method of preparing a coated C/C composite structure comprises the steps of: providing a C/C composite structure; applying a silicon based composition over the C/C composite structure by physical vapor deposition; forming a first layer comprising silicon carbide over the C/C composite by annealing the silicon based composition and the C/C composite at an annealing temperature; and applying a second layer comprising boron over the first layer by physical vapor deposition.

### TECHNICAL FIELD

Embodiments of the present invention generally relate to carbon/carbon (C/C) composite structures, and specifically relate to methods of preparing C/C composite structures.

### SUMMARY

C/C composites exhibit high strength, high fracture toughness, low density, high thermal conductivity and high electrical conductivity. However, the present inventors have recognized that C/C composites tend to deteriorate in oxidizing environments, for example, in oxidizing environments wherein the temperature exceeds approximately 300° C. Because of oxidation, the C/C composites may lose weight and mass, due to the formation of CO and CO₂ gas. Furthermore, the oxidation may weaken the mechanical strength, functionality and operability of the C/C composites.

In order to protect C/C composites, barrier coatings are often applied on the surface of the C/C composites. However, the present inventors have recognized that traditionally used barrier coatings tend to form cracks during heat cycles because of the coefficient of thermal expansion (CTE) mismatch. Due to the CTE mismatch, the oxygen may penetrate through the crack and attack the C/C composite, thus resulting in weight loss and inoperability of the C/C composite. Thus, there exists a need for improved C/C composites and methods of making the C/C composites.

According to one embodiment, a method of preparing a coated C/C composite structure is provided. The method comprises the steps of: providing a C/C composite structure; applying a silicon based composition over the C/C composite structure by physical vapor deposition; forming a first layer comprising silicon carbide on the C/C composite by annealing the silicon based composition and the C/C composite at an annealing temperature; and applying a second layer comprising boron over the first layer by physical vapor deposition. As used herein, “over” means directly on the layer without intervening layers, or allows intervening layers therebetween.

According to another embodiment, a method of preparing a coated C/C composite structure is provided. The method comprises the steps of: providing a C/C composite structure; applying a silicon based composition on the C/C composite structure by physical vapor deposition; forming a first layer comprising silicon carbide on the C/C composite by annealing the silicon based composition and the C/C composite at an annealing temperature at or above the melting point of silicon; and filling cracks in the first layer by applying a second layer comprising boron, silicon, and oxygen on the first layer by physical vapor deposition, wherein the second layer forms a borosilicate glass phase in the cracks of the first layer.

These and additional objects and advantages provided by the embodiments of the present invention will be more fully understood in view of the following detailed description, in conjunction with the drawings.

### BRIEF DESCRIPTION OF THE DRAWINGS

The following detailed description of specific embodiments of the present invention can be best understood when read in conjunction with the drawings enclosed herewith. The drawing sheets include:

FIG. 1 is a flow chart illustrating the method of preparing a coated C/C composite structure according to one or more embodiments of the present invention;

FIG. 2a is an optical micrograph depicting a cross-sectional view of a Si based composition layer on the C/C composite structure according to one or more embodiments of the present invention;

FIG. 2b is an optical micrograph depicting a surface view of a Si based composition layer on the C/C composite structure according to one or more embodiments of the present invention;

FIG. 3 is an optical micrograph illustrating the micro-cracks on the SiC layer according to one or more embodiments of the present invention;

FIG. 4 is an X-Ray Diffraction (XRD) spectrum of the C/C composite structure after formation of the SiC layer due to annealing according to one or more embodiments of the present invention;

FIG. 5a is an optical micrograph depicting a surface view of a boron coated C/C composite structure according to one or more embodiments of the present invention;

FIG. 5b is another optical micrograph of different resolution depicting a surface view of a boron coated C/C composite structure according to one or more embodiments of the present invention;

FIG. 6a is an optical micrograph depicting a cross sectional view of a boron coated C/C composite structure according to one or more embodiments of the present invention; and

FIG. 6b is another optical micrograph of different resolution depicting a cross sectional view of a boron coated C/C composite structure according to one or more embodiments of the present invention.

The embodiments set forth in the drawings are illustrative in nature and not intended to be limiting of the invention defined by the claims. Moreover, individual features of the drawings and the invention will be more fully apparent and understood in view of the detailed description.

### DETAILED DESCRIPTION

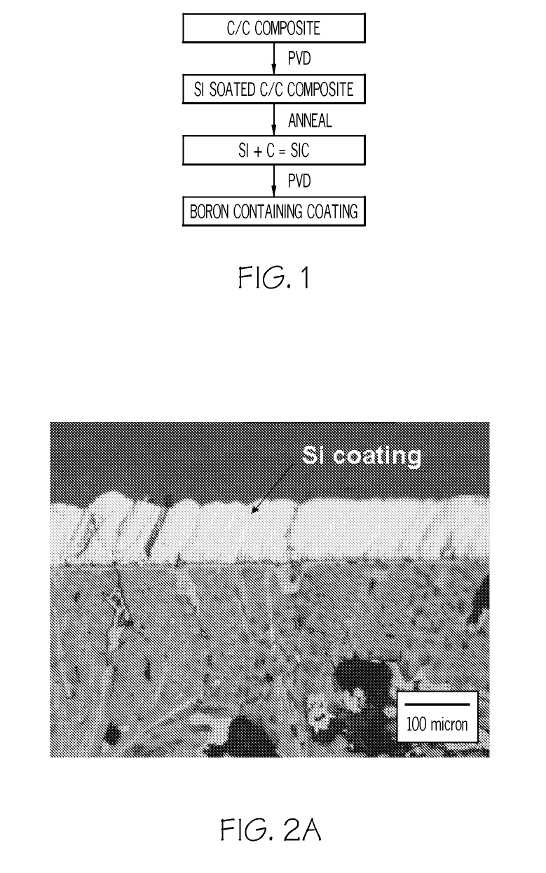

Referring to FIG. 1, the present invention relates to coated C/C composite structures and specifically relates to methods of preparing coated C/C structures. As used herein, “C/C composite” refers to composite materials comprising reinforced carbon fibers, carbon matrices, graphite, graphite-like materials, and modified carbon materials with the exception of diamond. The method of producing the coated C/C composite first comprises the step of providing a C/C composite structure. In accordance with one embodiment, the C/C composite structure may be simply obtained from a suppler. For example, BF Goodrich supplies C/C composite structures in the form of aircraft brakes.

Alternatively, C/C composite structures may be prepared from carbon fibers. Carbon fibers may comprise various materials known to one of ordinary skill in the art. For example, and not by way of limitation, the carbon fibers may be formed from pre-oxidized acrylonitrile resin. In one embodiment, these carbon fibers are layered together to form a structure, for example, a friction brake structure. The structure is then heated and infiltrated with a pyrolyzable carbon source to form the C/C composites. Pyrolyzable carbon sources may include methane or other suitable sources operable to transform a composition in the presence of heat. The properties of the C/C composite may be varied as desired by the user. In a couple exemplary embodiments, the C/C composite may have a density from about 1.6 to about 1.9 g/cm³, or specifically a density of about 1.75 g/cm³.

After a C/C composite structure has been provided, a silicon based composition is applied over the C/C composite structure by physical vapor deposition (PVD). In one embodiment, the C/C composite structure may be polished prior to the application of the silicon based composition. For example, and not by way of limitation, the C/C composite structure may be polished using 600 grit silicon carbide paper. As stated above, the silicon based composition is deposited by physical vapor deposition, which may encompass multiple suitable deposition techniques. The physical vapor deposition techniques may include, but are not limited to, e-beam physical vapor deposition, thermal evaporation, arc discharge, or combinations thereof. PVD provides advantages in silicon application, for example, efficiency, reduced deposition times, and reduced costs. In contrast, chemical vapor deposition (CVD) methods require handling of highly corrosive and toxic gases. Furthermore, the gas delivery and scrubbing systems for CVD are expensive, thus increasing the life cycle cost of the C/C components. Also, the process is slow and takes several days for coating deposition.

In specific industrial embodiments of C/C composite structures, e.g. aircraft brakes, the thickness of the coating is an important consideration. Applying thick silicon based coatings on the C/C composite will provide better protection against oxidation; however, these thick coatings may suffer significant weight penalty, i.e., weight increase is not good, as well as undesirable loss of the dimensional tolerance. Consequently, the thickness of Si coating should be optimized to maximize oxidation protection and minimize the weight penalty and size changes of the C/C composite structure. In one exemplary embodiment, a silicon based composition may be deposited to a total thickness of about 100 μm to about 150 μm. In a further embodiment, the silicon based composition was deposited using a deposition rate of about 20 μm/hour. The silicon based composition comprises silicon or silicon based compounds known to one of ordinary skill in the art, especially compounds which adhere well and uniformly cover the surface of C/C composites.

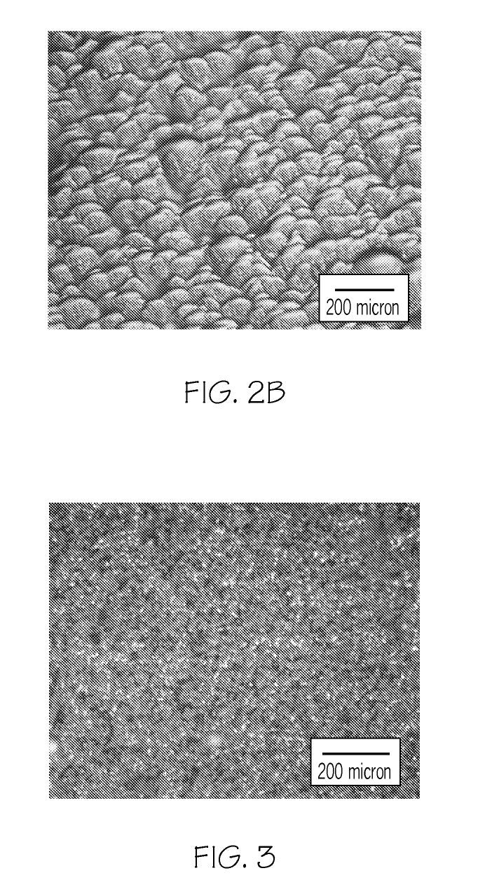

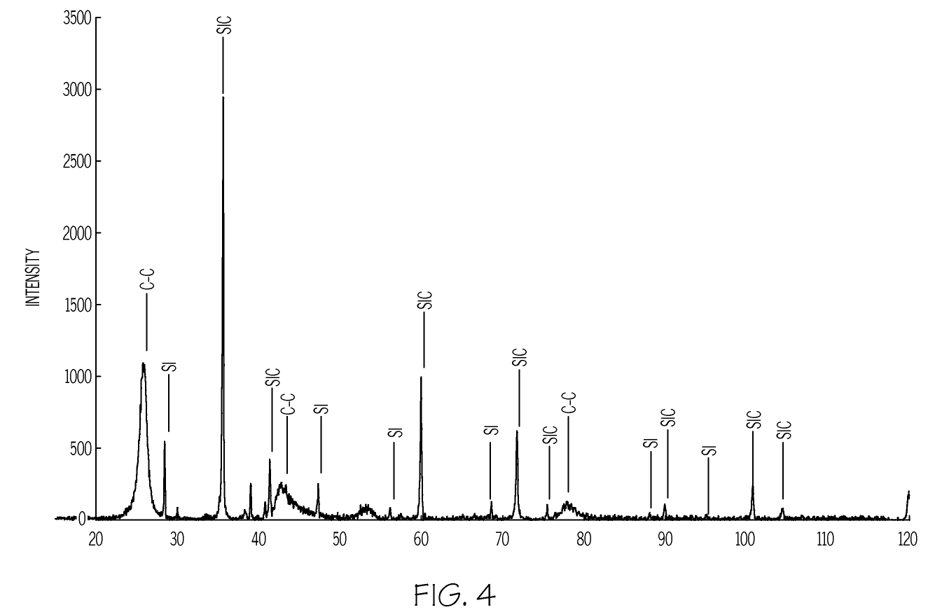

After the deposition of silicon on the C/C composite structure, the silicon containing composition and C/C composite structure is annealed at a temperature sufficient to convert silicon to form a first layer of silicon carbide over the C/C composite structure. Silicon carbide (SiC) is an excellent oxidation resistant and chemically compatible protective coating for C/C composite structures. At the annealing temperature, the carbon of the C/C composite structure reacts with the deposited silicon to produce silicon carbide. In one embodiment, the annealing temperature is at least the temperature of the melting point of silicon. In a further embodiment, the annealing temperature is at or above about 1450° C. For example, and not by way of limitation, the annealing process may occur in a furnace operating at or above about 1450° C. in the presence of an argon atmosphere. The resulting SiC coated C/C composite structures are illustrated in the micrographs of FIGS. 2a and 2b. Furthermore, the XRD graph of FIG. 4 further characterizes the transformation of Si to SiC after annealing.

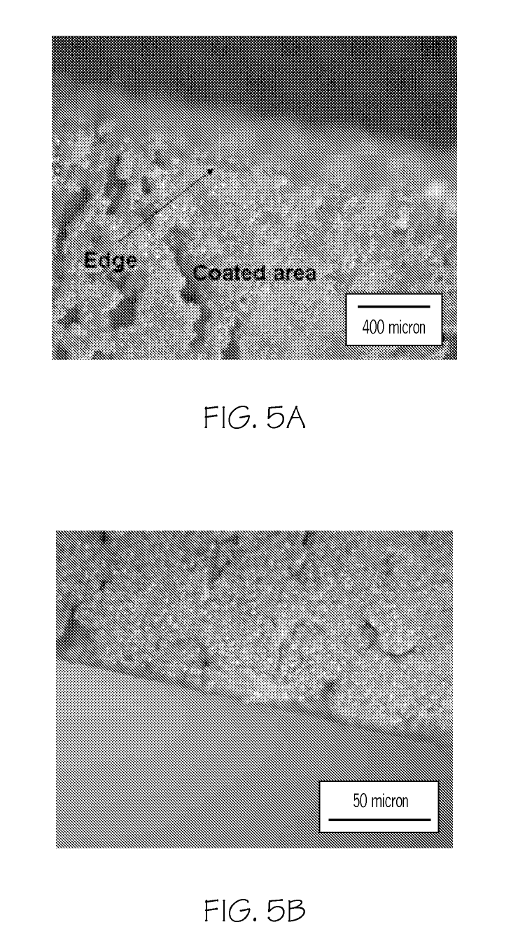

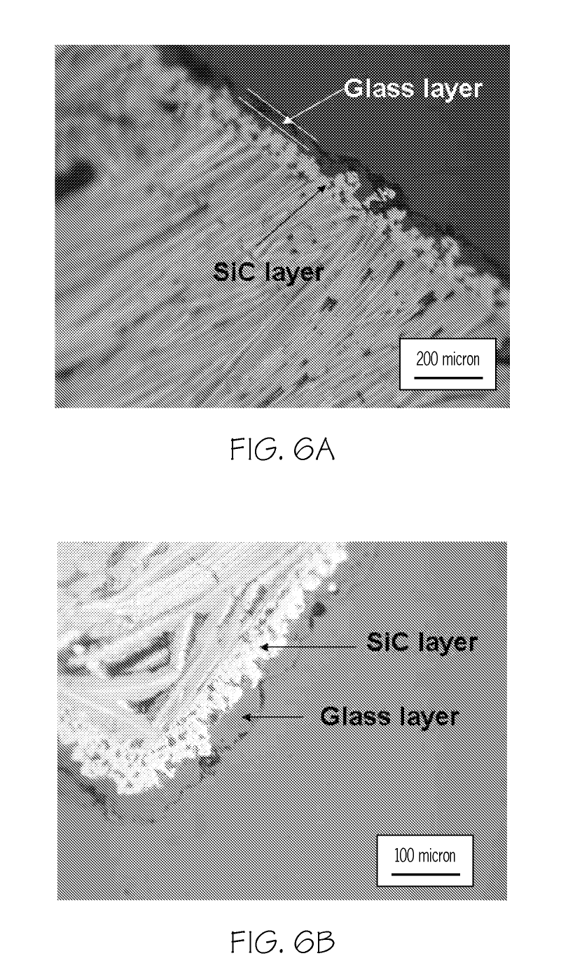

Despite the benefits of the SiC layer, micro-cracks may form in the SiC layer as shown in FIG. 3, due to the coefficient of thermal expansion (CTE) mismatch between the C/C composite structure, (1×10⁻⁶ K⁻¹ in fiber direction) and SiC (5×10⁻⁶ K⁻¹). For effective oxidation protection, these cracks need to be filled. Consequently, the present method includes the step of applying a second layer comprising boron on the first layer of SiC by physical vapor deposition. As shown in FIGS. 5a, 5b, 6a, and 6b, the second boron containing layer will be deposited through PVD as the sealing agent on the SiC surface to eliminate the micro-cracks. In one embodiment, the boron containing layer can prevent oxidation through cracks in the SiC layer by forming a borosilicate glassy phase. In addition to boron, the boron containing second layer may comprise other elements or compounds, for example, silicon, oxygen or combinations thereof. In an exemplary embodiment, the second layer comprises a composition having about 10 to about 30 wt % boron, about 30 to about 60 wt % silicon, and about 20 to about 50% wt % oxygen. Like the silicon application step, the second boron containing layer may be deposited using various PVD techniques, for example, e-beam PVD. The second boron containing layer will be deposited to a thickness amount sufficient for filling the micro-cracks in the SiC layer. The thicknesses and depositon rates of the boron containing layer may vary as desired by the user. In one embodiment, the boron containing layer comprises a thickness of about 50 to about 100 μm, and the deposition rate was about 0.5 to about 1.0 μm per minute.

Upon filling the micro-cracks with the boron containing layer, a coated C/C structure with an oxidation resistance at temperatures at or above 1600° F. is produced. The data obtained in Experimental Example 1 below further illustrates the excellent mechanical oxidation resistant properties of the coated C/C composite structure.

### EXPERIMENTAL EXAMPLE 1

For cyclic oxidation tests, coated C/C composite structure samples were placed on an alumina rack and then inserted manually into and out of a Rapid Temp resistantly-heated furnace with an air-flow rate of 1000 ml/min. Each sample was isothermally oxidized at 1600° F. for one-hour increments and then quenched in air to room temperature. Once cooled, each sample was weighed using a Mettler AE100 microbalance (changes 0.1 mg), and the weight changes were calculated and recorded. All samples lasted through the entire test (30 hours at 1250° F. and 20 hours at 1600° F.) with minimal total weight loss (<2 wt %).

It is noted that terms like “specifically,” “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention. It is also noted that terms like “substantially” and “about” are utilized herein to represent the inherent degree of uncertainty that may be attributed to any quantitative comparison, value, measurement, or other representation.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A method of preparing a coated C/C composite structure comprising:
providing a C/C composite structure;
applying a silicon based composition over the C/C composite structure by physical vapor deposition;
forming a first layer comprising silicon carbide over the C/C composite by annealing the silicon based composition and the C/C composite at an annealing temperature; and
applying a second layer comprising boron over the first layer by physical vapor deposition.

2. A method according to claim 1 wherein the second layer fills in cracks present in the first layer.

3. A method according to claim 2 wherein the second layer forms a borosilicate glass phase in the cracks of the first layer.

4. A method according to claim 1 wherein the annealing temperature is at or above the melting point of silicon.

5. A method according to claim 1 wherein the annealing temperature is at or above about 1450° C.

6. A method according to claim 1 wherein the annealing occurs in an argon atmosphere.

7. A method according to claim 1 wherein the physical vapor deposition methods comprise e-beam physical vapor deposition, thermal evaporation, arc discharge, or combinations thereof.

8. A method according to claim 1 further comprising polishing the C/C composite structure prior to the application of the silicon based composition.

9. A method according to claim 1 wherein the physical vapor deposition methods define a deposition rate of about 20 μm/hour.

10. A method according to claim 1 wherein the silicon containing compound is applied to a thickness of about 100 to about 150 μm.

11. A method according to claim 1 wherein the boron containing second layer comprises silicon, oxygen or combinations thereof.

12. A method according to claim 1 wherein the second layer comprises a composition having about 10 to about 30 wt % boron, about 30 to about 60 wt % silicon, and about 20 to about 50% wt % oxygen.

13. A coated C/C composite structure produced by the method of claim 1.

14. A coated C/C composite structure of claim 13 wherein the C/C structure is resistant to oxidation at 1600° F.

15. An aircraft brake comprising the coated C/C composite structure of claim 13.

16. A method according to claim 1 wherein the provided C/C composite structure is prepared from carbon fibers.

17. A method according to claim 16 wherein the carbon fibers comprise acrylonitrile resin.

18. A method according to claim 16 wherein the preparation of the C/C composite comprises:
layering the carbon fibers; and
heating the carbon fibers in the presence of a pyrolyzable carbon source to produce a C/C composite.

19. A method of preparing a coated C/C composite structure comprising:
providing a C/C composite structure;
applying a silicon based composition over the C/C composite structure by physical vapor deposition;
forming a first layer comprising silicon carbide over the C/C composite by annealing the silicon based composition and the C/C composite at an annealing temperature at or above the melting point of silicon; and
filling cracks in the first layer by applying a second layer comprising boron, silicon, and oxygen over the first layer by physical vapor deposition, wherein the second layer forms a borosilicate glass phase in the cracks of the first layer.
